(19) United States
(12) Patent Application Publication
(10) Pub. No.: US 2018/0155957 A1
(43) Pub. Date: Jun. 7, 2018

(54) METHOD FOR WATERPROOFING A LOCK DEVICE

(71) Applicant: Mul-T-Lock Technologies Ltd., Yavne (IL)

(72) Inventor: Aharon VARDI, Ashdod (IL)

(73) Assignee: Mul-T-Lock Technologies Ltd., Yavne (IL)

(21) Appl. No.: 15/575,371

(22) PCT Filed: May 5, 2016
(86) PCT No.: PCT/IB2016/052573

§ 371 Date: Nov. 19, 2017

(30) Foreign Application Priority Data
May 19, 2015 (IL) 238909

(51) Int. Cl. E05B 17/00; E05B 77/34; C23C 16/24

(52) U.S. Cl. CPC E05B 17/002; C23C 16/24; E05B 77/34

(57) ABSTRACT

A method for waterproofmg a lock device includes applying a hydrophobic coating on internal components of a lock device, the components including a movable plug and plug pins.

### FIELD OF THE INVENTION

The present invention generally relates to lock devices, such as mechanical and electromechanical locks, and more specifically to protecting such locks with a hydrophobic coating.

### BACKGROUND OF THE INVENTION

There are many situations where it is desired to prevent water from entering a cylinder lock or other similar lock device. For example, water entering a cylinder lock can cause corrosion in the plug, plug pins or driver pins and prevent proper operation of the cylinder lock. In electromechanical locks, there is the additional problem of water contacting electrical circuitry and causing short circuits.

The problem of waterproofing a cylinder lock has been addressed in the prior art. The typical prior art solution is the use of a sealing device, such as a seal, gasket or other sealing member, which seals the entrance to the keyway in the lock. This solution is deficient for several reasons. For example, if the seal just covers the keyway opening, it does not seal the space between the cylinder lock plug and the cylinder housing and water can enter. Even if the seal covers the entire entrance to the cylinder lock, the seal must be removed before using the lock which makes the solution cumbersome to use. The seal can also fall off or get lost. Even worse, if water gets past the seal, the seal prevents the water from exiting, thereby accelerating corrosion formation.

### SUMMARY OF THE INVENTION

The present invention seeks to provide an improved method for waterproofing a cylinder lock, padlock and the like, with a hydrophobic coating, as is described in detail further hereinbelow. The invention may be used for mechanical, mechatronic and electromechanical lock devices. The hydrophobic coating is thin and does not significantly add to the outer dimensions of the components and of the lock device. This is an important advantage over the prior art. The components and lock device can fit into a volume that the prior art cannot achieve.

Examples of lock devices for which the invention is applicable include, without limitation, mechanical padlocks or cylinder locks, mechatronic padlocks or cylinder locks and electromechanical padlocks or cylinder locks,

A mechatronic padlock is a device with an integrated or a remote electronic system, which operates after verifying the authorization of a user.

A mechatronic cylinder lock is a device with an integrated or a remote electronic system, which is to be used with a lock for the purpose of operating the lock after verifying the authorization of an electronic key.

The invention is applicable for electronic or electromechanical keys and remote control devices, such as keypads, fingerprint sensor devices for locks, RFID (radio frequency identification), RC (radio or remote control) and others. The hydrophobic coating does away for the need for caps or other seals.

The hydrophobic coating can be optically transparent or RF transparent and therefore suitable for covering optical elements, such as LEDs, or RF components, such as transceivers or transducers.

Electromechanical locking devices require contacts that interface with a key device. In the prior art, the contacts are protected from water or other moisture by a removable cap or other seal in the keyway. The use of the cap depends on the user. There are situations where the cap must be removed even if rain is falling on the lock device. The hydrophobic coating does away for the need for caps or other seals. Even if water enters the device, the hydrophobic coating protects the components.

There is thus provided in accordance with an embodiment of the present invention a method for waterproofing a lock device including applying a hydrophobic coating on internal components of a lock device, the components including a movable plug and plug pins. The components may further include driver pins and springs, bolt throwing elements and/or electrical components.

In accordance with an embodiment of the present invention the hydrophobic coating is applied on the internal components after the internal components are assembled in the lock device.

In accordance with another embodiment of the present invention the hydrophobic coating is applied on the internal components before the internal components are assembled in the lock device.

The lock device may include a mechanical lock, an electromechanical lock, a cylinder lock, a padlock, or a key (e.g., an electronic or electromechanical key).

### BRIEF DESCRIPTION OF THE DRAWINGS

The present invention will be understood and appreciated more fully from the following detailed description taken in conjunction with the drawing in which:

FIG. 1 is a simplified flow chart of a method for waterproofing a lock device in accordance with a non-limiting embodiment of the present invention.

### DETAILED DESCRIPTION OF EMBODIMENTS

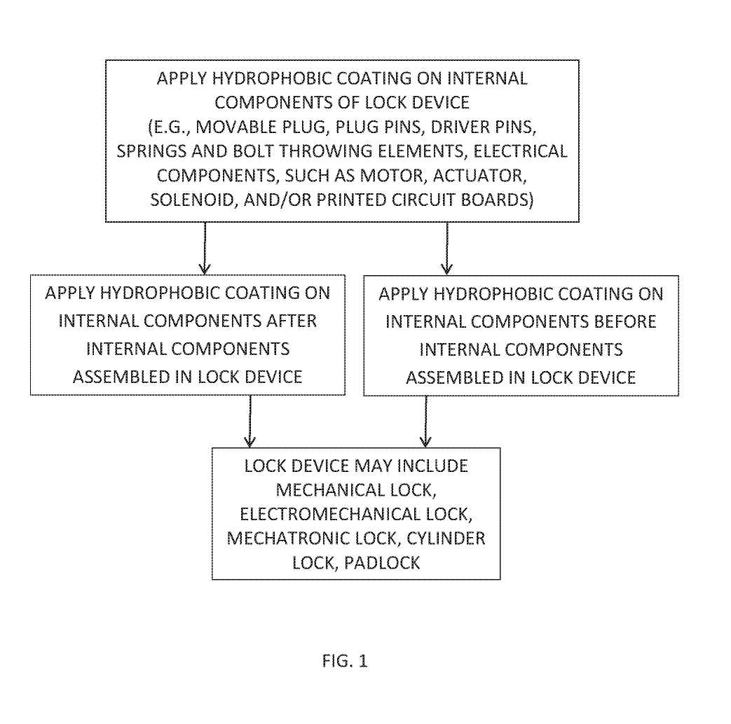

Reference is now made to FIG. 1, which illustrates a method for waterproofing a lock device in accordance with a non-limiting embodiment of the present invention.

In contrast with the prior art methods of sealing to prevent ingress of water into the lock, in the present invention, no attempt is made to prevent water from entering. Instead waterproof protection is provided by application of a hydrophobic coating on some or all of the inner components of the lock device. Examples are given below for applying the hydrophobic coating.

In one embodiment, the hydrophobic coating is applied on the internal components of the lock device before the internal components are assembled in the lock device. For example, for a mechanical lock device, the movable (e.g., rotatable) plug, plug pins, driver pins, springs and bolt throwing elements (such as latches, cams, levers, etc.) are coated with a hydrophobic coating and then assembled in the lock. For an electromechanical or mechatronic lock device, in addition to any movable plug, plug pins, driver pins, springs and bolt throwing elements (such as latches, cams, levers, etc.), any electrical components (e.g., motor, actuator, solenoid and the like) and/or printed circuit boards are coated with a hydrophobic coating and then assembled in the lock.

In another embodiment, the hydrophobic coating is applied on the internal components of the lock device after the internal components are assembled in the lock device. For example, for a mechanical lock device, the plug, plug pins, driver pins, springs and cam or cams are coated with a hydrophobic coating after having been assembled in the lock. For an electromechanical or mechatronic lock device, in addition to any plug, plug pins, driver pins, springs and cam or cams, any electrical components and/or printed circuit boards are coated with a hydrophobic coating after having been assembled in the lock. This embodiment has the advantage of significant savings in time and money. In addition, this embodiment has the advantage of being applicable to lock devices that have been previously manufactured and for which it is desired to waterproof.

In yet another embodiment, the hydrophobic coating is applied on an electromechanical key, defined as a key on which key cuts are to be cut for interfacing with elements when the key is inserted in a keyway of a lock device and which includes electrical/electronic components for effecting authorization of the key with the lock device. The hydrophobic coating protects electrical/electronic components of the electromechanical key from damaging effects of moisture.

Examples of method for applying the hydrophobic coating include, without limitation, chemical and physical coating processes, such as sol-gel coating processes. The solution (“sol”) gradually forms a gel-like diphasic system (“gel”) containing hydrophobic nano-particles which are included within a polymer network. These nano-particles coat the component surfaces. The coating is applied by using simple dipping (such as dipping the completely assembled lock device in the hydrophobic solution or dipping the individual components in the solution before assembly) or spraying processes (such as spraying the completely assembled lock device with the hydrophobic solution, wherein the sprayed solution covers the components by flowing into the lock device, or spraying the individual components with the solution before assembly) followed by a hardening process. In principal, all those coatings can be applied to all kind of materials which can withstand the necessary temperatures for the hardening process, and is thus applicable for both mechanical and electromechanical locks.

An example of such a sol-gel hydrophobic coating is described in PCT patent application WO 03/094574. The example is a biofilm-inhibiting coating of an inorganic condensate modified with organic groups on the basis of a coating composition, which includes a hydrolysate or pre-condensate of one or more hydrolysable compounds with at least one non-hydrolysable substituent, whereby at least one part of the organic groups of the condensate exhibits fluorine atoms and/or copper or silver colloids are contained in the coating.

Other examples of hydrophobic coatings include, without limitation, different silicone compounds, such as silicone polymers, poly-metric siloxanes, reactive silane monomers, siliconates, hydrated silanes (hydro-silicones), organic silicon-containing materials and others. Silicone compounds may be dissolved or thinned with a liquid solvent and the mixed solution or emulsion is sprayed onto the components or finished assembly, followed by drying.

Another example of a suitable hydrophobic conformal coating is a chemical vapor deposition (CVD) process. There are many types of CVD processes, which can be used to carry out the invention, including but not limited to, atmospheric CVD, low pressure CVD, ultra-high vacuum CVD and different kinds of plasma-assisted CVD. The invention is not limited to any particular process. The hydrophobic coating can be between 1 and 3 microns thick, or other thicknesses depending on the need and application. An example of a hydrophobic coating is a parylene coating.

The terms waterproof, water-resistant and water-repelling are used interchangeably in the specification and claims.

The International Electrotechnical Commission (IEC) standard 60529, inter alia, defines degrees of protection against water. The following table summarizes the levels of protection:

| | Protected | | |
|---|---|---|---|
| Level | against | Testing for | Details |
| 0 | Not | — | — |
| | protected | | |
| 1 | Dripping | Dripping water (vertically | Test duration: 10 |
| | water | falling drops) shall have | minutes |
| | | no harmful effect. | Water equivalent |
| | | | to 1 mm rainfall |
| | | | per minute |
| 2 | Dripping | Vertically dripping water | Test duration: 10 |
| | water | shall have no harmful | minutes |
| | when | effect when the enclosure | Water equivalent |
| | tilted | is tilted at an angle up | to 3 mm rainfall |
| | up to | to 15° from its normal | per minute |
| | 15° | position. | |
| 3 | Spraying | Water falling as a spray | Test duration: 5 |
| | water | at any angle up to 60° | minutes |
| | | from the vertical shall | Water volume per |
| | | have no harmful effect. | time: 0.7 lit/min |
| | | | Pressure: 80-100 |
| | | | kPa |
| 4 | Splashing | Water splashing against | Test duration: 5 |
| | of water | the enclosure from any | minutes |
| | | direction shall have no | Water volume per |
| | | harmful effect. | time: 10 lit/min |
| | | | Pressure: 80-100 |
| | | | kPa |
| 5 | Water | Water projected by a | Test duration: at |
| | jets | nozzle (6.3 mm) against | least 3 minutes |
| | | enclosure from any | Water volume per |
| | | direction shall have no | time: 12.5 lit/min |
| | | harmful effects. | Pressure: 30 kPa |
| | | | at distance of 3 m |
| 6 | Powerful | Water projected in | Test duration: at |
| | water | powerful jets (12.5 mm | least 3 minutes |
| | jets | nozzle) against the | Water volume per |
| | | enclosure from any | time: 100 lit/min |
| | | direction shall have | Pressure: 100 kPa |
| | | no harmful effects. | at distance of 3 m |
| 6K | Powerful | Water projected in | Test duration: at |
| | water | powerful jets (6.3 mm | least 3 minutes |
| | jets with | nozzle) against the | Water volume per |
| | increased | enclosure from any | time: 75 lit/min |
| | pressure | direction, under | Pressure: 1000 kPa |
| | | elevated pressure, | at distance of 3 m |
| | | shall have no | |
| | | harmful effects. | |
| 7 | Immersion | Ingress of water in | Test duration: 30 |
| | up to 1 m | harmful quantity | minutes |
| | | shall not be possible | The lowest point |
| | | when the enclosure | of enclosures with |
| | | is immersed in water | a height less than |
| | | under defined | 850 mm is located |
| | | conditions of pressure | 1000 mm below the |
| | | and time (up to 1 m | surface of the |
| | | of submersion). | water, the highest |
| | | | point of enclosures |
| | | | with a height equal |
| | | | to or greater than |
| | | | 850 mm is located |
| | | | 150 mm below the |
| | | | surface of the |
| | | | water |
| 8 | Immersion | The equipment is | Test duration: |
| | beyond | suitable for continuous | continuous |
| | 1 m | immersion in water | immersion in water |
| | | under conditions which | Depth specified |
| | | shall be specified by | by manufacturer, |
| | | the manufacturer. | generally up to |
| | | However, with certain | 3 m |
| | | types of equipment, it | |
| | | can mean that water can | |
| | | enter but only in such | |
| | | a manner that it | |
| | | produces no harmful | |
| | | effects. | |
| 9K | Powerful | Protected against | — |
| | high | close-range high | |
| | temper- | pressure, high | |
| | ature | temperature spray | |
| | water | downs. | |
| | jets | | |

The waterproofing achieved with the methods of the invention can be used to comply with IEC standard 60529 levels 1-6K, or to levels 1-8 or to levels 1-9K.

What is claimed is:

1. A method for waterproofing a lock device comprising:
applying a hydrophobic coating on internal components of a lock device, said lock device comprising a mechanical lock device, an electromechanical lock device or a mechatronic lock device.

2. The method according to claim 1, wherein said internal components include a movable plug.

3. The method according to claim 1, wherein said internal components include plug pins, driver pins and springs.

4. The method according to claim 1, wherein said internal components include bolt throwing elements.

5. The method according to claim 1, wherein said internal components include electrical components or a printed circuit board.

6. The method according to claim 1, wherein said hydrophobic coating is applied on the internal components after the internal components are assembled in the lock device.

7. The method according to claim 1, wherein said hydrophobic coating is applied on the internal components before the internal components are assembled in the lock device.

8. The method according to claim 1, wherein said lock device comprises a cylinder lock.

9. The method according to claim 1, wherein said lock device comprises a padlock.

10. The method according to claim 1, wherein said hydrophobic coating comprises a sol-gel coating.

11. The method according to claim 1, wherein said hydrophobic coating comprises a parylene coating.

12. The method according to claim 1, wherein said hydrophobic coating comprises a silicone compound.

13. The method according to claim 1, wherein said hydrophobic coating is applied by a chemical vapor deposition (CVD) process.

14. A device comprising an electromechanical key with a hydrophobic coating applied thereon.
